(19) United States
(12) Patent Application Publication
(10) Pub. No.: US 2021/0006274 A1
(43) Pub. Date: Jan. 7, 2021

(54) RADIO FREQUENCY FRONT END CIRCUIT AND COMMUNICATION DEVICE

(71) Applicant: Murata Manufacturing Co., Ltd., Kyoto (JP)

(72) Inventor: Hiroyuki KANI, Kyoto (JP)

(21) Appl. No.: 17/029,195

(22) Filed: Sep. 23, 2020

Related U.S. Application Data
(63) Continuation of application No. PCT/JP2019/005844, filed on Feb. 18, 2019.

(30) Foreign Application Priority Data
Mar. 29, 2018 (JP) 2018-065593

(51) Int. Cl. H04B 1/00; H04B 1/50; H04B 1/48

(52) U.S. Cl. CPC H04B 1/0057; H04B 1/48; H04B 1/50

(57) ABSTRACT

A radio frequency front end circuit includes a diplexer, two reception filters having, as pass bands, a band of a low frequency side band group and a band of a high frequency side band group, and a transmission/reception filter in which a pass band overlaps a boundary band of the low frequency side band group and the high frequency side band group, in which the diplexer includes a low frequency side filter connected to a common terminal and a first input/output terminal and a high frequency side filter connected to the common terminal and a second input/output terminal, the common terminal is connected to a common input/output terminal, the one reception filter is connected to the first input/output terminal, the other reception filter is connected to the second input/output terminal, and the transmission/reception filter is connected to the common input/output terminal without passing through the diplexer.

This is a continuation of International Application No. PCT/JP2019/005844 filed on Feb. 18, 2019 which claims priority from Japanese Patent Application No. 2018-065593 filed on Mar. 29, 2018. The contents of these applications are incorporated herein by reference in their entireties.

### BACKGROUND OF THE DISCLOSURE

### 1. Field of the Disclosure

The present disclosure relates to a radio frequency front end circuit and a communication device.

### 2. Description of the Related Art

In recent communication services, carrier aggregation (hereinafter, referred to as CA) for simultaneously using a plurality of communication bands is executed for a purpose of increasing communication capacity. In order to realize CA operation for the purpose of increasing the communication capacity, radio frequency front end circuits are required to demultiplex adjacent bands into multiple bands while reducing loss and size reduction.

US Patent Application Publication No. 2014/133364 discloses a radio frequency front end circuit capable of executing CA by using two communication bands. The radio frequency front end circuit disclosed in US Patent Application Publication No. 2014/133364 includes a diplexer (multiplexer) constituted by a low pass filter having a low frequency side frequency band group as a pass band and a high pass filter having a high frequency side frequency band group as a pass band, and a plurality of band pass filters connected to the diplexer and having respective communication bands as pass bands. According to this configuration, when CA is executed using one frequency band belonging to the low frequency side frequency band group (band A) and another frequency band belonging to the high frequency side frequency band group (band B), a radio frequency signal in the one frequency band passes through the low pass filter of the diplexer, and a radio frequency signal in the other frequency band passes through the high pass filter of the diplexer. This makes it possible to realize low-loss CA operation in which interference between the radio frequency signal in the one frequency band and the radio frequency signal in the other frequency band that execute CA is reduced.

For each of the low pass filter and the high pass filter constituting the diplexer disclosed in US Patent Application Publication No. 2014/133364, it is difficult to ensure the steepness of bandpass characteristics at a boundary between the low frequency side band group and the high frequency side band group. Therefore, insertion loss of a high frequency side end band of the pass band of the low pass filter deteriorates, and insertion loss of a low frequency side end band of the pass band of the high pass filter deteriorates. For this reason, when at least one of the band A and the band B that execute CA is located in a boundary band including a pass band high end of the low pass filter in which the insertion loss deteriorates and a pass band low end of the high pass filter in which the insertion loss deteriorates, there is a problem in that transmission loss of the radio frequency signal in the at least one band that overlaps the boundary band (insertion loss of the radio frequency front end circuit) increases.

### BRIEF SUMMARY OF THE DISCLOSURE

Accordingly, the present disclosure has been made in order to solve the above problem, and an object of the present disclosure is to provide a radio frequency front end circuit and a communication device capable of executing low-loss CA with a simplified circuit configuration even when a radio frequency signal in a boundary band is used as CA.

In order to achieve the above object, a radio frequency front end circuit according to an aspect of the present disclosure is capable of simultaneously transmitting a radio frequency signal in one or more frequency bands of a plurality of frequency bands belonging to a first frequency band group, and a radio frequency signal in one or more frequency bands of a plurality of frequency bands belonging to a second frequency band group located on a high frequency side of the first frequency band group, and includes: a common input/output terminal connected to an antenna; a multiplexer including a first common terminal, a first input/output terminal, and a second input/output terminal, and performing at least one of demultiplexing and multiplexing of a high frequency signal in the first frequency band group and a high frequency signal in the second frequency band group; a first filter having a first frequency band belonging to the first frequency band group as a pass band; a second filter having a second frequency band belonging to the second frequency band group as a pass band; and a third filter having a frequency band on a higher frequency side than the first frequency band and on a lower frequency side than the second frequency band as a pass band overlapping a boundary band of the first frequency band group and the second frequency band group, the boundary band including a high frequency side end band of the first frequency band group and a low frequency side end band of the second frequency band group, in which the multiplexer includes a low frequency side filter connected between the first common terminal and the first input/output terminal and having a plurality of frequency bands belonging to the first frequency band group as a pass band and a plurality of frequency bands belonging to the second frequency band group as an attenuation band, and a high frequency side filter connected between the first common terminal and the second input/output terminal and having a plurality of frequency bands belonging to the second frequency band group as a pass band and a plurality of frequency bands belonging to the first frequency band group as an attenuation band, the first common terminal is connected to the common input/output terminal, one end of the first filter is connected to the first input/output terminal, one end of the second filter is connected to the second input/output terminal, and one end of the third filter is connected to the common input/output terminal without passing through the multiplexer.

Other features, elements, characteristics and advantages of the present disclosure will become more apparent from the following detailed description of preferred embodiments of the present disclosure with reference to the attached drawings.

### BRIEF DESCRIPTION OF THE SEVERAL VIEWS OF THE DRAWINGS

FIG. 1A is a circuit configuration diagram of a communication device according to Embodiment 1;

FIG. 1B is a diagram illustrating a frequency relationship between bandpass characteristics of a diplexer included in a radio frequency front end circuit according to Embodiment 1 and bands for executing CA;

FIG. 2A is a circuit configuration diagram of a radio frequency front end circuit according to Modification 1 of Embodiment 1;

FIG. 2B is a circuit configuration diagram of a radio frequency front end circuit according to Modification 2 of Embodiment 1;

FIG. 3A is a circuit configuration diagram of a radio frequency front end circuit according to Embodiment 2;

FIG. 3B is a diagram illustrating a frequency relationship between bandpass characteristics of a diplexer included in the radio frequency front end circuit according to Embodiment 2 and bands for executing CA;

FIG. 4A is a circuit configuration diagram of a radio frequency front end circuit according to Modification of Embodiment 2;

FIG. 4B is a diagram illustrating a frequency relationship between bandpass characteristics of a diplexer included in the radio frequency front end circuit according to Modification of Embodiment 2 and bands for executing CA;

FIG. 5A is a circuit configuration diagram of a radio frequency front end circuit according to Embodiment 3; and

FIG. 5B is a diagram illustrating a frequency relationship between bandpass characteristics of a diplexer included in the radio frequency front end circuit according to Embodiment 3 and bands of LTE.

### DETAILED DESCRIPTION OF THE DISCLOSURE

Hereinafter, Embodiments of the present disclosure will be described in detail with reference to the accompanying drawings. It should be noted that all of the embodiments and modifications described below are comprehensive or specific examples. Numerical values, shapes, materials, constituent elements, arrangement and connection forms of the constituent elements, and the like illustrated in the following embodiments and modifications are mere examples, and are not intended to limit the present disclosure. Among the constituent elements in the following embodiments and modifications, the constituent elements that are not described in the independent claims are explained as optional constituent elements. In addition, the sizes or ratio of sizes of the constituent elements illustrated in the drawings are not necessarily strict.

### Embodiment 1

### 1.1 Configuration of Communication Device According to Embodiment 1

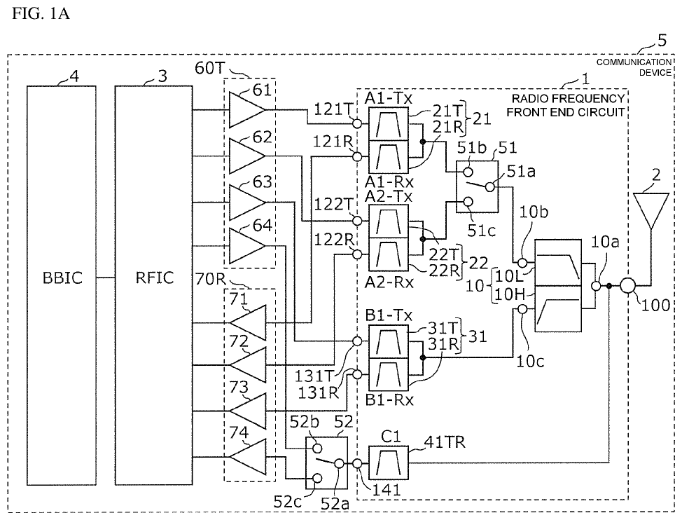

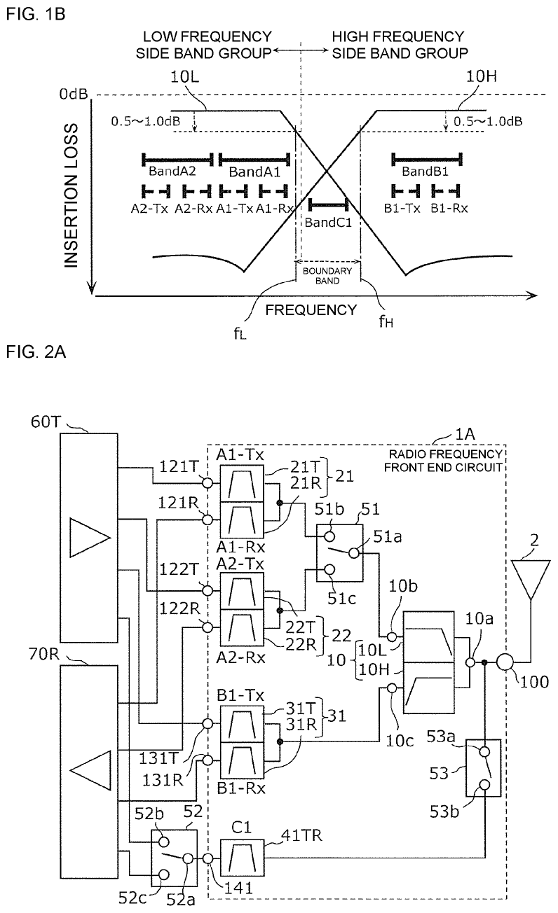

FIG. 1A is a circuit configuration diagram of a communication device 5 according to Embodiment 1. As illustrated in the figure, the communication device 5 includes an antenna element 2, a radio frequency front end circuit 1, a switch 52, a transmission amplifier circuit 60T, a reception amplifier circuit 70R, a radio frequency integrated circuit (RFIC) 3, and a baseband integrated circuit (BBIC) 4.

First, a detailed configuration of the radio frequency front end circuit 1 will be described.

FIG. 1B is a diagram illustrating a frequency relationship between bandpass characteristics of a diplexer 10 included in the radio frequency front end circuit 1 according to Embodiment 1 and the respective bands for executing CA.

As illustrated in FIG. 1A, the radio frequency front end circuit 1 is a front end circuit that processes both a radio frequency transmission signal and a radio frequency reception signal, and includes the diplexer 10, duplexers 21, 22, and 31, a transmission/reception filter 41TR, a switch 51, and a common input/output terminal 100.

The common input/output terminal 100 is connected to the antenna element 2.

The diplexer 10 includes a common terminal 10a (first common terminal), an input/output terminal 10b (first input/output terminal), and an input/output terminal 10c (second input/output terminal), and is a multiplexer that demultiplexes and multiplexes radio frequency signals in a low frequency side band group (first frequency band group) and radio frequency signals in a high frequency side band group (second frequency band group) located on a high frequency side for the low frequency side band group.

Note that the diplexer 10 may be a multiplexer that demultiplexes and multiplexes the radio frequency signals in the two frequency band groups as in the present embodiment, and may be a multiplexer that demultiplexes and multiplexes radio frequency signals in three or more frequency band groups.

Note that the low frequency side band group is, for example, a frequency band group including a plurality of bands located on a low frequency side of the respective bands of long term evolution (LTE), and the high frequency side band group is, for example, a frequency band group including a plurality of bands located on a high frequency side of the respective bands of LTE, and is a band group located on a higher frequency side than the low frequency side band group.

The diplexer 10 includes a low frequency side filter 10L and a high frequency side filter 10H. The low frequency side filter 10L is connected between the common terminal 10a and the input/output terminal 10b, and is a low pass filter that has a plurality of frequency bands belonging to the low frequency side band group as a pass band, and a plurality of frequency bands belonging to the high frequency side band group as an attenuation band, as illustrated in FIG. 1B. Also, the high frequency side filter 10H is connected between the common terminal 10a and the input/output terminal 10c, and is a high pass filter that has a plurality of frequency bands belonging to the high frequency side band group as a pass band, and a plurality of frequency bands belonging to the low frequency side band group as an attenuation band, as illustrated in FIG. 1B. In addition, the common terminal 10a is connected to the common input/output terminal 100.

The duplexer 21 is constituted by a transmission filter 21T and a reception filter 21R. The transmission filter 21T is a first filter having a transmission band A1-Tx of a band A1 (first frequency band) belonging to the low frequency side band group as a pass band. Further, the reception filter 21R is a first filter having a reception band A1-Rx of the band A1 (first frequency band) belonging to the low frequency side band group as a pass band. One end of the transmission filter 21T and one end of the reception filter 21R are both connected to the input/output terminal 10b via the switch 51. Further, another end of the transmission filter 21T is connected to an input/output terminal 121T, and another end of the reception filter 21R is connected to an input/output terminal 121R.

The duplexer 22 is constituted by a transmission filter 22T and a reception filter 22R. The transmission filter 22T is a filter having a transmission band A2-Tx of a band A2 belonging to the low frequency side band group as a pass band. Further, the reception filter 22R is a filter having a reception band A2-Rx of the band A2 belonging to the low frequency side band group as a pass band. One end of the transmission filter 22T and one end of the reception filter 22R are both connected to the input/output terminal 10b via the switch 51. Further, another end of the transmission filter 22T is connected to an input/output terminal 122T, and another end of the reception filter 22R is connected to an input/output terminal 122R.

The duplexer 31 is constituted by a transmission filter 31T and a reception filter 31R. The transmission filter 31T is a second filter having a transmission band B1-Tx of a band B1 (second frequency band) belonging to the high frequency side band group as a pass band. Further, the reception filter 31R is a second filter having a reception band B1-Rx of the band B1 (second frequency band) belonging to the high frequency side band group as a pass band. One end of the transmission filter 31T and one end of the reception filter 31R are both connected to the input/output terminal 10c. Further, another end of the transmission filter 31T is connected to an input/output terminal 131T, and another end of the reception filter 31R is connected to an input/output terminal 131R.

Note that each of the duplexers 21, 22, and 31 may be a filter constituted by only a transmission filter or only a reception filter.

As illustrated in FIG. 1B, the transmission/reception filter 41TR is a third filter having a band C1 (third frequency band) located on a higher frequency side than the bands A1 and A2 and on a lower frequency side than the band B1 as a pass band. At least a part of the band C1 (third frequency band) overlaps the boundary band of the low frequency side band group and the high frequency side band group. Note that, in the present embodiment, the band C1 belongs to the high frequency side band group depending on combination for executing CA, but the band C1 may belong to the low frequency side band group depending on the combination.

Here, the boundary band of the low frequency side band group and the high frequency side band group is a band including a high frequency side end band of the low frequency side band group and a low frequency side end band of the high frequency side band group. More specifically, as illustrated in FIG. 1B, the boundary band of the low frequency side band group and the high frequency side band group is defined as a frequency band between a frequency F_{L} at which a predetermined insertion loss amount increases from the minimum insertion loss of the low frequency side filter 10L and a frequency F_{H} at which the predetermined insertion loss amount increases from the minimum insertion loss of the high frequency side filter 10H. Note that the predetermined insertion loss is 0.5 dB to 1.0 dB.

Note that when there is a plurality of frequencies at which the predetermined insertion loss amount increases from the minimum insertion loss of the low frequency side filter 10L, of the plurality of frequencies, a frequency that is located on the highest frequency side, which is the lower frequency side than the high frequency side band group, is defined as the frequency F_{L}. Also, when there is a plurality of frequencies at which the predetermined insertion loss amount increases from the minimum insertion loss of the high frequency side filter 10H, of the plurality of frequencies, a frequency that is located on the lowest frequency side, which is the higher frequency side than the low frequency side band group, is defined as the frequency F_{H}.

In the radio frequency front end circuit 1 according to the present embodiment, one end of the transmission/reception filter 41TR is connected to the common input/output terminal 100 without passing through the diplexer 10. Further, another end of the transmission/reception filter 41TR is connected to an input/output terminal 141.

According to the above configuration, the radio frequency front end circuit 1 can simultaneously transmit (execute CA) radio frequency signals in one or more frequency bands of the plurality of frequency bands (band A1 and band A2) belonging to the low frequency side band group and radio frequency signals in one or more frequency bands of the plurality of frequency bands (band B1 and band C1) belonging to the high frequency side band group. The radio frequency signals for executing CA pass through the low frequency side filter 10L or the high frequency side filter 10H, and thus it is possible to attenuate unnecessary waves and harmonic waves in a higher order mode generated due to the radio frequency signals.

In particular, the radio frequency front end circuit 1 can execute CA that simultaneously transmits at least two of the radio frequency signal in the band A1 (first frequency band) passing through the duplexer 21, the radio frequency signal in the band B1 (second frequency band) passing through the duplexer 31, and the radio frequency signal in the band C1 (third frequency band) passing through the transmission/reception filter 41TR.

Here, as the bandpass characteristics of the duplexer 10, as illustrated in FIG. 1B, the insertion loss of the low frequency side filter 10L is larger in the boundary band than in the bands A1 and A2. Further, the insertion loss of the high frequency side filter 10H is larger in the boundary band than in the band B1.

In the low frequency side filter 10L that constitutes the diplexer 10, it is difficult to ensure the steepness of the bandpass characteristic at the boundary between the low frequency side band group and the high frequency side band group, because the wide band low frequency side band group including the plurality of frequency bands is set as the pass band and the wide band high frequency side band group including the plurality of frequency bands is set as the attenuation band. Further, in the high frequency side filter 10H, it is difficult to ensure the steepness of the bandpass characteristic at the boundary between the low frequency side band group and the high frequency side band group, because the wide band high frequency side band group is set as the pass band and the wide band low frequency side band group is set as the attenuation band. For this reason, when at least one of the two bands for executing CA is located in the boundary band including the pass band high end of the low frequency side filter 10L and the pass band low end of the high frequency side filter 10H in which the insertion loss deteriorates, the transmission loss of the radio frequency signal in the at least one band that overlaps the boundary band increases. In particular, when a space between the low frequency side band group and the high frequency side band group is narrow, the insertion loss in the high frequency side end band of the pass band of the low frequency side filter 10L is likely to deteriorate, and the insertion loss in the low frequency side end band of the pass band of the high frequency side filter 10H is likely to deteriorate.

On the other hand, according to the above configuration, (1) the radio frequency signal in the band A1 or band A2 and the radio frequency signal in the band B1 can be simultaneously transmitted. In this case, the radio frequency signal in the band A1 passes through the low frequency side filter 10L and the duplexer 21 (or the radio frequency signal in the band A2 passes through the low frequency side filter 10L and the duplexer 22), and the radio frequency signal in the band B1 passes through the high frequency side filter 10H and the duplexer 31. In addition, (2) the radio frequency signal in the band C1 and the radio frequency signal in the band A1 or A2 can be simultaneously transmitted. In this case, the radio frequency signal in the band C1 passes through only the transmission/reception filter 41TR without passing through the high frequency side filter 10H and the radio frequency signal in the band A1 passes through the low frequency side filter 10L and the duplexer 21 (or the radio frequency signal in the band A2 passes through the low frequency side filter 10L and the duplexer 22).

That is, when the radio frequency signal in the band C1 which at least partially overlaps the boundary band and the radio frequency signal in the band A1 or the band A2 which does not overlap the boundary band are simultaneously transmitted, the radio frequency signal in the band C1 is set so as not to pass through the diplexer 10 in which the insertion loss deteriorates in the boundary band. In addition, by not allowing the radio frequency signal in the band C1 which at least partially overlaps the boundary band to pass through the diplexer 10, it is possible to relax the required specifications (for the insertion loss and the attenuation amount) of the diplexer 10 in the boundary band. Therefore, even when a radio frequency signal in the boundary band is used as CA, low-loss CA can be achieved by a simplified circuit configuration without complicating the diplexer 10.

The switch 51 includes a common terminal 51a, selection terminals 51b and 51c, switches connection and non-connection between the low frequency side filter 10L and the duplexer 21, and switches connection and non-connection between the low frequency side filter 10L and the duplexer 22. The switch 51 is, for example, a single pole double throw (SPDT) switch.

Further, the switch 52 includes a common terminal 52a, selection terminals 52b and 52c, and exclusively switches connection between the transmission/reception filter 41TR and a transmission amplifier 64, and connection between the transmission/reception filter 41TR and a reception amplifier 74. The switch 52 is, for example, the SPDT switch.

Note that the radio frequency front end circuit 1 according to the present embodiment may not include the duplexer 22. In this case, the radio frequency front end circuit 1 can execute (1) CA using the band A1 and the band B1 and (2) CA using the band A1 and the band C1. In this case, the switch 51 is not required.

Further, the transmission/reception filter 41TR may be any one of a transmission filter and a reception filter, and may be a duplexer having a transmission filter and a reception filter individually. In this case, the switch 52 is not required.

The RFIC 3 is a radio frequency integrated circuit that processes a radio frequency signal transmitted and received by the antenna element 2. Specifically, the RFIC 3 processes a radio frequency reception signal inputted from the antenna element 2 via the radio frequency front end circuit 1 and the reception amplifier circuit 70R by down-conversion or the like, and outputs the radio frequency reception signal generated by the signal processing to the BBIC 4. Further, the RFIC 3 processes a transmission signal inputted from the BBIC 4 by up-conversion or the like, and outputs the radio frequency transmission signal generated by the signal processing to the transmission amplifier circuit 60T and the radio frequency front end circuit 1.

Furthermore, in the present embodiment, the RFIC 3 also has a function as a control unit that controls the connection of the switches 51 and 52 included in the communication device 5 based on the band (frequency band) to be used. Specifically, the RFIC 3 switches the connection of the switches 51 and 52 by a control signal (not illustrated). Note that the control unit may be provided outside the RFIC 3, and may be provided in, for example, the radio frequency front end circuit 1 or the BBIC 4.

The transmission amplifier circuit 60T includes transmission amplifiers 61, 62, 63, and 64, amplifies a radio frequency transmission signal output from the RFIC 3, and outputs the amplified radio frequency transmission signal to the radio frequency front end circuit 1. The transmission amplifier 61 has an input terminal connected to the RFIC 3, and an output terminal connected to the input/output terminal 121T, and amplifies the radio frequency transmission signal in the band A1. The transmission amplifier 62 has an input terminal connected to the RFIC 3, and an output terminal connected to the input/output terminal 122T, and amplifies the radio frequency transmission signal in the band A2. The transmission amplifier 63 has an input terminal connected to the RFIC 3, and an output terminal connected to the input/output terminal 131T, and amplifies the radio frequency transmission signal in the band B1. The transmission amplifier 64 has an input terminal connected to the RFIC 3, and an output terminal connected to the selection terminal 52b, and amplifies the radio frequency transmission signal in the band C1.

Note that, instead of the transmission amplifiers 61 to 64 that are arranged individually as corresponding to the respective bands, a transmission amplifier capable of amplifying radio frequency transmission signals in the plurality of bands may be arranged. In this case, the number of transmission amplifiers can be reduced, but a switch for switching a signal path is added to at least one of a preceding stage and a subsequent stage of the transmission amplifier.

The reception amplifier circuit 70R includes reception amplifiers 71, 72, 73, and 74, amplifies a radio frequency reception signal received by the antenna element 2 and passed through the radio frequency front end circuit 1, and outputs the amplified radio frequency reception signal to the RFIC 3. The reception amplifier 71 has an output terminal connected to the RFIC 3, and an input terminal connected to the input/output terminal 121R, and amplifies the radio frequency reception signal in the band A1. The reception amplifier 72 has an output terminal connected to the RFIC 3, and an input terminal connected to the input/output terminal 122R, and amplifies the radio frequency reception signal in the band A2. The reception amplifier 73 has an output terminal connected to the RFIC 3, and an input terminal connected to the input/output terminal 131R, and amplifies the radio frequency reception signal in the band B1. The reception amplifier 74 has an output terminal connected to the RFIC 3, and an input terminal connected to the selection terminal 52c, and amplifies the radio frequency reception signal in the band C1.

Note that, instead of the reception amplifiers 71 to 74 that are arranged individually as corresponding to the respective bands, a reception amplifier capable of amplifying radio frequency reception signals in the plurality of bands may be arranged. In this case, the number of reception amplifiers can be reduced, but a switch for switching a signal path is added to at least one of a preceding stage and a subsequent stage of the reception amplifier.

Note that, in the present embodiment, the switch 52, the transmission amplifier circuit 60T, and the reception amplifier circuit 70R are provided separately from the radio frequency front end circuit 1 and are included in the communication device 5. However, the switch 52, the transmission amplifier circuit 60T, and the reception amplifier circuit 70R may be included in the radio frequency front end circuit 1.

According to the above-described configuration of the communication device 5, even when the radio frequency signal in the boundary band is used as CA, the radio frequency front end circuit 1 enables low-loss CA. Therefore, a gain of the transmission amplifier circuit 60T and a gain of the reception amplifier circuit 70R can be relaxed, and power consumption of the communication device 5 can be reduced. Further, it is possible to provide the communication device 5 capable of executing low-loss CA with a simplified circuit configuration without complicating the diplexer 10.

### 1.2 Configuration of Radio Frequency Front End Circuit According to Modification 1

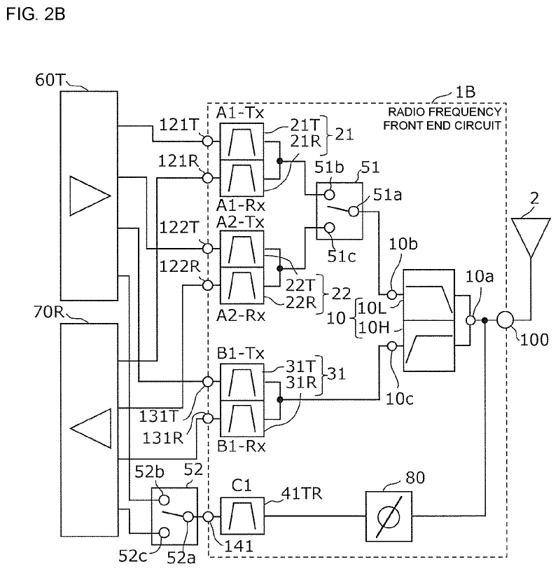

FIG. 2A is a circuit configuration diagram of a radio frequency front end circuit 1A according to Modification 1 of Embodiment 1. As illustrated in the figure, the radio frequency front end circuit 1A according to the present modification includes the diplexer 10, the duplexers 21, 22, and 31, the transmission/reception filter 41TR, the switch 51 and a switch 53, and the common input/output terminal 100.

The radio frequency front end circuit 1A according to the present modification differs from the radio frequency front end circuit 1 according to Embodiment 1 only in that the switch 53 is added. Hereinafter, for the radio frequency front end circuit 1A, the description of the same configuration as that of the radio frequency front end circuit 1 according to Embodiment 1 will be omitted and a different configuration will be mainly described.

The switch 53 has terminals 53a and 53b, and switches connection and non-connection between the transmission/reception filter 41TR and the common input/output terminal 100. The terminal 53b is connected to one end of the transmission/reception filter 41TR, and the terminal 53a is connected to the common input/output terminal 100. The switch 53 is, for example, a single pole single throw (SPST) switch.

Accordingly, (1) when CA using the radio frequency signal in the band A1 or the band A2 and the radio frequency signal in the band B1 is executed, it becomes possible to disconnect the transmission/reception filter 41TR from the common input/output terminal 100 by setting the switch 53 to be in a non-conductive state. Therefore, even when the phase adjustment between the duplexer 31 (band B1) and the transmission/reception filter 41TR (band C1) is not performed, it is possible to enable low-loss CA while ensuring isolation between a signal path of the band B1 and a signal path of the band C1.

### 1.3 Configuration of Radio Frequency Front End Circuit According to Modification 2

FIG. 2B is a circuit configuration diagram of a radio frequency front end circuit 1B according to Modification 2 of Embodiment 1. As illustrated in the figure, the radio frequency front end circuit 1B according to the present modification includes the diplexer 10, the duplexers 21, 22, and 31, the transmission/reception filter 41TR, the switch 51, a phase shifter 80, and the common input/output terminal 100.

The radio frequency front end circuit 1B according to the present modification differs from the radio frequency front end circuit 1 according to Embodiment 1 only in that the phase shifter 80 is added. Hereinafter, for the radio frequency front end circuit 1B, the description of the same configuration as that of the radio frequency front end circuit 1 according to Embodiment 1 will be omitted and a different configuration will be mainly described.

The phase shifter 80 is connected between the one end of the transmission/reception filter 41TR and the common input/output terminal 100.

Accordingly, (1) when CA using the radio frequency signal in the band A1 or the band A2 and the radio frequency signal in the band B1 is executed, the impedance in the band B1 can be set to high impedance (open state) when the transmission/reception filter 41TR is viewed from the common input/output terminal 100. Therefore, it is possible to enable low-loss CA while ensuring isolation between a signal path of the band B1 and a signal path of the band C1. Further, even when the band B1 and the band C1 overlap, it is possible to enable low-loss CA while ensuring isolation between the signal path of the band B1 and the signal path of the band C1.

### Embodiment 2

A radio frequency front end circuit 1C according to the present embodiment has a configuration in which, a radio frequency signal in one of a transmission band and a reception band constituting one frequency band is allowed to pass through the diplexer 10 and a radio frequency signal in another band is not allowed to pass through the diplexer 10.

### 2.1 Configuration of Radio Frequency Front End Circuit According to Embodiment 2

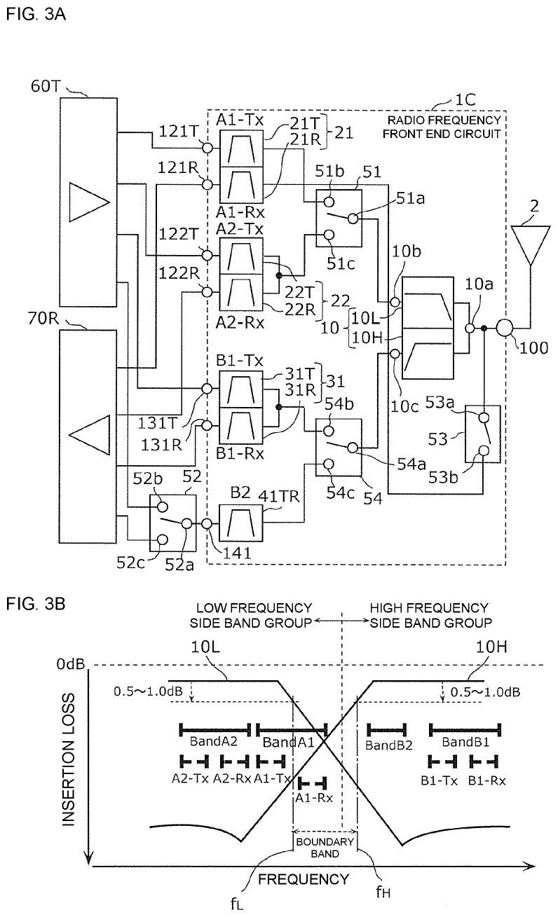

FIG. 3A is a circuit configuration diagram of the radio frequency front end circuit 1C according to Embodiment 2. FIG. 3B is a diagram illustrating a frequency relationship between bandpass characteristics of the diplexer 10 included in the radio frequency front end circuit 1C according to Embodiment 2 and bands for executing CA.

As illustrated in FIG. 3A, the radio frequency front end circuit 1C includes the diplexer 10, the duplexers 21, 22, and 31, the transmission/reception filter 41TR, the switches 51 and 53, and a switch 54, and the common input/output terminal 100.

The radio frequency front end circuit 1C according to the present embodiment differs from the radio frequency front end circuit 1 according to Embodiment 1 in that the switches 53 and 54 are added and the connection configuration of the duplexer 21 is different. Hereinafter, for the radio frequency front end circuit 1C according to the present embodiment, the description of the same configuration as that of the radio frequency front end circuit 1 according to Embodiment 1 will be omitted and a different configuration will be mainly described.

The diplexer 10 includes the low frequency side filter 10L and the high frequency side filter 10H. The low frequency side filter 10L is connected between the common terminal 10a and the input/output terminal 10b, and is a low pass filter that has a plurality of frequency bands (bands A1 and A2) belonging to a low frequency side band group as a pass band, and a plurality of frequency bands (bands B1 and B2) belonging to a high frequency side band group as an attenuation band, as illustrated in FIG. 3B. Also, the high frequency side filter 10H is connected between the common terminal 10a and the input/output terminal 10c, and is a high pass filter that has the plurality of frequency bands (bands B1 and B2) belonging to the high frequency side band group as a pass band, and the plurality of frequency bands (bands A1 and A2) belonging to the low frequency side band group as an attenuation band, as illustrated in FIG. 3B. In addition, the common terminal 10a is connected to the common input/output terminal 100.

The duplexer 21 is constituted by the transmission filter 21T and the reception filter 21R. The transmission filter 21T is a fifth filter having the transmission band A1-Tx of the band A1 (third frequency band in the present embodiment) belonging to the low frequency side band group as a pass band. Further, the reception filter 21R is a third filter having the reception band A1-Rx of the band A1 (third frequency band in the present embodiment) belonging to the low frequency side band group as a pass band. One end of the transmission filter 21T is connected to the input/output terminal 10b via the switch 51. On the other hand, one end of the reception filter 21R is connected to the common input/output terminal 100 via the switch 53 without passing through the diplexer 10. Further, the other end of the transmission filter 21T is connected to the input/output terminal 121T, and the other end of the reception filter 21R is connected to the input/output terminal 121R.

The duplexer 22 is constituted by the transmission filter 22T and the reception filter 22R. The transmission filter 22T is a first filter having the transmission band A2-Tx of the band A2 (first frequency band in the present embodiment) belonging to the low frequency side band group as a pass band. Further, the reception filter 22R is the first filter having the reception band A2-Rx of the band A2 (first frequency band in the present embodiment) belonging to the low frequency side band group as a pass band. One end of the transmission filter 22T and one end of the reception filter 22R are connected to the input/output terminal 10b via the switch 51. Further, the other end of the transmission filter 22T is connected to the input/output terminal 122T, and the other end of the reception filter 22R is connected to the input/output terminal 122R.

The duplexer 31 is constituted by the transmission filter 31T and the reception filter 31R. The transmission filter 31T is a second filter having the transmission band B1-Tx of the band B1 (second frequency band) belonging to the high frequency side band group as a pass band. Further, the reception filter 31R is the second filter having the reception band B1-Rx of the band B1 (second frequency band) belonging to the high frequency side band group as a pass band. One end of the transmission filter 31T and one end of the reception filter 31R are connected to the input/output terminal 10c via the switch 54. Further, the other end of the transmission filter 31T is connected to the input/output terminal 131T, and the other end of the reception filter 31R is connected to the input/output terminal 131R.

The transmission/reception filter 41TR is a filter having a band B2 belonging to the high frequency side band group as a pass band. One end of the transmission/reception filter 41TR is connected to the input/output terminal 10c via the switch 54. Further, the other end of the transmission/reception filter 41TR is connected to the input/output terminal 141.

Note that each of the duplexers 22 and 31 may be a filter constituted by only a transmission filter or only a reception filter. In addition, the transmission/reception filter 41TR may be a duplexer constituted by a transmission filter having a transmission band B2-Tx of the band B2 as a pass band and a reception filter having a band B2-Rx of the reception band B2 as a pass band.

As illustrated in FIG. 3B, band A1 (transmission band A1-Tx and reception band A1-Rx) is located between the band A2 and the bands B1 and B2. At least a part of the reception band A1-Rx overlaps a boundary band of the low frequency side band group and the high frequency side band group. On the other hand, the transmission band A1-Tx does not overlap the boundary band. Note that, in the present embodiment, the band A1 belongs to the low frequency side band group depending on combination of executing CA, but the band A1 may belong to the high frequency side band group depending on the combination. Further, depending on a frequency relationship between the transmission band A1-Tx and the reception band A1-Rx, at least a part of the transmission band A1-Tx may overlap the boundary band and the reception band A1-Rx may not overlap the boundary band.

Here, the boundary band of the low frequency side band group and the high frequency side band group is the same as the definition in Embodiment 1, and is the band including the high frequency side end band of the low frequency side band group and the low frequency side end band of the high frequency side band group. More specifically, as illustrated in FIG. 3B, the boundary band of the low frequency side band group and the high frequency side band group is defined as the frequency band between the frequency F_{L} at which a predetermined insertion loss amount increases from the minimum insertion loss of the low frequency side filter 10L and the frequency F_{H} at which the predetermined insertion loss amount increases from the minimum insertion loss of the high frequency side filter 10H. Note that the predetermined insertion loss is 0.5 dB to 1.0 dB.

According to the above-described configuration, the radio frequency front end circuit 1C can simultaneously transmit (execute CA) radio frequency signals in one or more frequency bands of the plurality of frequency bands (band A1 and band A2) belonging to the low frequency side band group and radio frequency signals in one or more frequency bands of the plurality of frequency bands (band B1 and band B2) belonging to the high frequency side band group.

Here, as the pass characteristics of the diplexer 10, as illustrated in FIG. 3B, insertion loss of the low frequency side filter 10L is larger in the reception band A1-Rx that overlaps the boundary band than in the band A2 and the transmission band A1-Tx. Further, the insertion loss of the high frequency side filter 10H is larger in the boundary band than in the bands B1 and B2.

In the low frequency side filter 10L that constitutes the diplexer 10, it is difficult to ensure the steepness of the bandpass characteristic at the boundary between the low frequency side band group and the high frequency side band group, because a wide band low frequency side band group including the plurality of frequency bands is set as the pass band and the wide band high frequency side band group including the plurality of frequency bands is set as the attenuation band. Further, in the high frequency side filter 10H, it is difficult to ensure the steepness of the bandpass characteristic at the boundary between the low frequency side band group and the high frequency side band group, because the wide band high frequency side band group is set as the pass band and the wide band low frequency side band group is set as the attenuation band. Therefore, when an interval between the low frequency side band group and the high frequency side band group is narrow, the insertion loss of the high frequency side end band of the pass band of the low frequency side filter 10L deteriorates, and the insertion loss of the low frequency side end band of the pass band of the high frequency side filter 10H deteriorates.

In the radio frequency front end circuit 1C according to the present embodiment, the one end of the reception filter 21R is connected to the common input/output terminal 100 without passing through the diplexer 10. Further, the one end of the transmission filter 21T is connected to the diplexer 10.

That is, since the reception band A1-Rx included in the band A1 overlaps the boundary band, the reception filter 21R is set so as not to pass through the diplexer 10 in which the insertion loss deteriorates in the boundary band. On the other hand, the transmission filter 21T having the transmission band A1-Tx that does not overlap the boundary band as the pass band is set so as to pass through the diplexer 10. That is, the connection destinations of the transmission filter 21T and the reception filter 21R in the same band A1 are differentiated depending on whether or not each band overlaps the boundary band. Accordingly, even when the band A1 in the boundary band is used as CA, the radio frequency transmission signal in the band A1 is ensured to have low-loss and high isolation via the diplexer 10, and the radio frequency reception signal in the band A1 can be ensured to have low-loss without passing through the diplexer 10. Therefore, even when the radio frequency signal in the boundary band is used as CA, low-loss CA can be achieved in both of the transmission and reception signals without complicating the diplexer 10.

Note that the switch 51 has the common terminal 51a, the selection terminals 51b and 51c, switches connection and non-connection between the low frequency side filter 10L and the transmission filter 21T, and switches connection and non-connection between the low frequency side filter 10L and the duplexer 22. The switch 51 is, for example, an SPDT switch.

The switch 53 includes the terminals 53a and 53b, and switches the connection and non-connection between the reception filter 21R and the common input/output terminal 100. The terminal 53b is connected to the one end of the reception filter 21R, and the terminal 53a is connected to the common input/output terminal 100. The switch 53 is, for example, the SPST switch.

Accordingly, (1) when CA using the radio frequency signal in the band A2 and the radio frequency signal in the band B1 or B2 is executed, it becomes possible to disconnect the reception filter 21R from the common input/output terminal 100 by setting the switch 53 to be in a non-conductive state. Therefore, even when the phase adjustment between the duplexer 22 (band A2) and the reception filter 21R (band A1) is not performed, it is possible to ensure low-loss CA while ensuring isolation between a signal path of the band A2 and a signal path of the band A1. Further, even when the band A1 and the band A2 overlap, it is possible to enable low-loss CA while ensuring the isolation between the signal path of the band A1 and the signal path of the band A2.

Note that the radio frequency front end circuit 1C according to the present embodiment may not include the duplexer 22. In this case, the radio frequency front end circuit 1C can execute (1) CA using the band A1 and the band B1 and (2) CA using the band A1 and the band B2. In this case, the switch 51 is not required.

In addition, any one of the duplexer 31 and the transmission/reception filter 41TR may not be provided. In this case, the radio frequency front end circuit 1C can execute (1) CA using the band A1 and one of the bands B1 and B2 and (2) CA using the band A2 and one of the bands B1 and B2. In this case, the switch 54 is not required.

### 2.2 Configuration of Radio Frequency Front End Circuit According to Modification

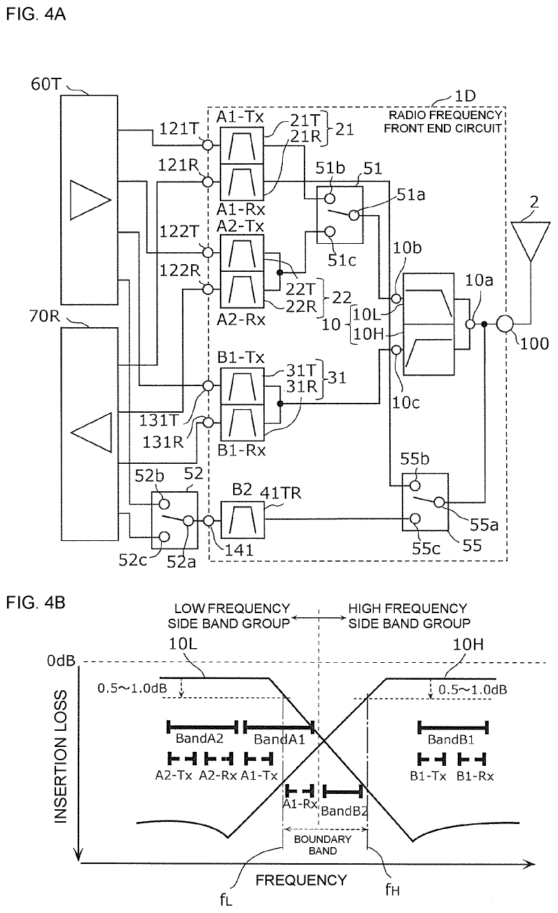

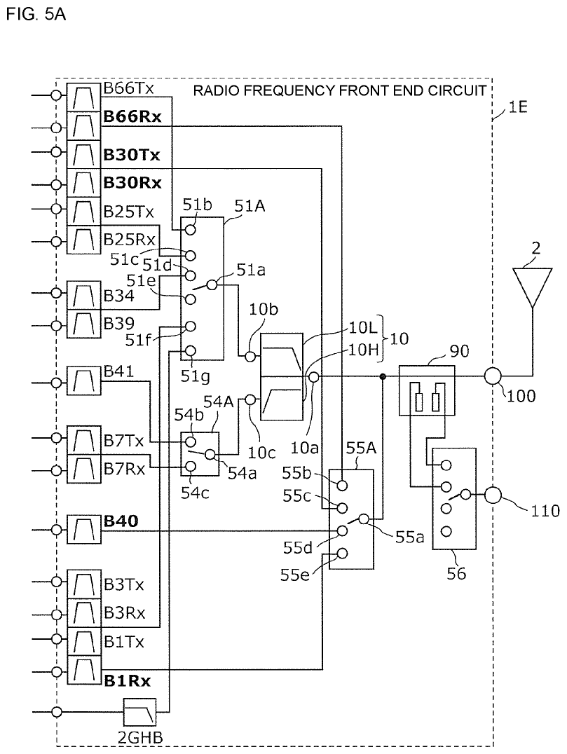

FIG. 4A is a circuit configuration diagram of a radio frequency front end circuit 1D according to Modification of Embodiment 2. FIG. 4B is a diagram illustrating a frequency relationship between bandpass characteristics of the diplexer 10 included in the radio frequency front end circuit 1D according to Modification of Embodiment 2 and bands for executing CA.

As illustrated in FIG. 4A, the radio frequency front end circuit 1D includes the diplexer 10, the duplexers 21, 22, and 31, the transmission/reception filter 41TR, the switch 51 and a switch 55, and the common input/output terminal 100.

The radio frequency front end circuit 1D according to the present modification differs from the radio frequency front end circuit 1C according to Embodiment 2 in that the switch 54 is not provided and the switch 55 is added, and the connection configurations of the duplexer 21 and the transmission/reception filter 41TR are different.

Hereinafter, for the radio frequency front end circuit 1D according to the present modification, the description of the same configuration as that of the radio frequency front end circuit 1C according to Embodiment 2 will be omitted and a different configuration will be mainly described.

The diplexer 10 includes the low frequency side filter 10L and the high frequency side filter 10H. The low frequency side filter 10L is connected between the common terminal 10a and the input/output terminal 10b, and is the low pass filter that has the plurality of frequency bands (bands A1 and A2) belonging to the low frequency side band group as the pass band, and the plurality of frequency bands (bands B1 and B2) belonging to the high frequency side band group as the attenuation band, as illustrated in FIG. 4B. Further, the high frequency side filter 10H is connected between the common terminal 10a and the input/output terminal 10c, and is the high pass filter that has the plurality of frequency bands (bands B1 and B2) belonging to the high frequency side band group as the pass bands, and the plurality of frequency bands (bands A1 and A2) belonging to the low frequency side band group as the attenuation bands, as illustrated in FIG. 4B. In addition, the common terminal 10a is connected to the common input/output terminal 100.

The duplexer 21 is constituted by the transmission filter 21T and the reception filter 21R. The transmission filter 21T is the fifth filter having the transmission band A1-Tx of the band A1 (third frequency band in the present modification) belonging to the low frequency side band group as the pass band. Further, the reception filter 21R is the third filter having the reception band A1-Rx of the band A1 (third frequency band in the present modification) belonging to the low frequency side band group as the pass band. The one end of the transmission filter 21T is connected to the input/output terminal 10b via the switch 51. On the other hand, the one end of the reception filter 21R is connected to the common input/output terminal 100 via the switch 55 without passing through the diplexer 10. Further, the other end of the transmission filter 21T is connected to the input/output terminal 121T, and the other end of the reception filter 21R is connected to the input/output terminal 121R.

The duplexer 22 is constituted by the transmission filter 22T and the reception filter 22R. The transmission filter 22T is the first filter having the transmission band A2-Tx of the band A2 (first frequency band in the present modification) belonging to the low frequency side band group as the pass band. Further, the reception filter 22R is the first filter having the reception band A2-Rx of the band A2 (first frequency band in the present modification) belonging to the low frequency side band group as the pass band.

The duplexer 31 is constituted by the transmission filter 31T and the reception filter 31R. The transmission filter 31T is the second filter having the transmission band B1-Tx of the band B1 (second frequency band) belonging to the high frequency side band group as the pass band. Further, the reception filter 31R is the second filter having the reception band B1-Rx of the band B1 (second frequency band) belonging to the high frequency side band group as the pass band. One end of the transmission filter 31T and one end of the reception filter 31R are connected to the input/output terminal 10c. Further, the other end of the transmission filter 31T is connected to the input/output terminal 131T, and the other end of the reception filter 31R is connected to the input/output terminal 131R.

The transmission/reception filter 41TR is the fourth filter having the band B2 (fourth frequency band in the present modification) belonging to the high frequency side band group as the pass band. One end of the transmission/reception filter 41TR is connected to the common input/output terminal 100 via the switch 55 without passing through the diplexer 10. Further, the other end of the transmission/reception filter 41TR is connected to the input/output terminal 141.

Note that each of the duplexers 21, 22 and 31 may be a filter constituted by only a transmission filter or only a reception filter. In addition, the transmission/reception filter 41TR may be the duplexer constituted by the transmission filter having the transmission band B2-Tx of the band B2 as the pass band and the reception filter having the reception band B2-Rx of the band B2 as the pass band.

As illustrated in FIG. 4B, band A1 (transmission band A1-Tx and reception band A1-Rx) is located between the band A2 and the bands B1 and B2. At least a part of the reception band A1-Rx overlaps the boundary band of the low frequency side band group and the high frequency side band group. On the other hand, the transmission band A1-Tx does not overlap the boundary band. The band B2 is located between the bands A1 and A2 and the band B1. At least a part of the band B2 overlaps the boundary band of the low frequency side band group and the high frequency side band group. Note that, in the present modification, the band A1 belongs to the low frequency side band group depending on combination of executing CA, but the band A1 may belong to the high frequency side band group depending on the combination. Further, in the present modification, the band B2 belongs to the high frequency side band group depending on the combination of executing CA, but the band B2 may belong to the low frequency side band group depending on the combination.

Note that the switch 55 includes a common terminal 55a (second common terminal) and selection terminals 55b (first selection terminal) and 55c (second selection terminal), switches connection and non-connection between the reception filter 21R and the common input/output terminal 100, and switches connection and non-connection between the transmission/reception filter 41TR and the common input/output terminal 100. The switch 55 is constituted by, for example, the SPDT switch or two SPST switches. The common terminal 55a of the switch 55 is connected to the common input/output terminal 100, the selection terminal 55b is connected to the one end of the reception filter 21R, and the selection terminal 55c is connected to the one end of the transmission/reception filter 41TR.

Here, the boundary band of the low frequency side band group and the high frequency side band group is the same as the definition in Embodiment 1, and is the band including the high frequency side end band of the low frequency side band group and the low frequency side end band of the high frequency side band group.

According to the above-described configuration, the radio frequency front end circuit 1D can simultaneously transmit (execute CA) radio frequency signals in one or more frequency bands of the plurality of frequency bands (band A1 and band A2) belonging to the low frequency side band group and radio frequency signals in one or more frequency bands of the plurality of frequency bands (band B1 and band B2) belonging to the high frequency side band group.

Here, as the pass characteristics of the diplexer 10, as illustrated in FIG. 4B, the insertion loss of the low frequency side filter 10L is larger in the reception band A1-Rx that overlaps the boundary band than in the band A2 and the transmission band A1-Tx. Further, the insertion loss of the high frequency side filter 10H is larger in the band B2 that overlaps the boundary band than in the band B1.

In the low frequency side filter 10L constituting the diplexer 10, it is difficult to ensure the steepness of the bandpass characteristic at the boundary between the low frequency side band group and the high frequency side band group. Further, in the high frequency side filter 10H, it is difficult to ensure the steepness of the bandpass characteristic at the boundary between the low frequency side band group and the high frequency side band group. Therefore, when the interval between the low frequency side band group and the high frequency side band group is narrow, the insertion loss of the high frequency side end band of the pass band of the low frequency side filter 10L deteriorates, and the insertion loss of the low frequency side end band of the pass band of the high frequency side filter 10H deteriorates.

In the radio frequency front end circuit 1D according to the present embodiment, (1) simultaneous transmission of the radio frequency signal in the band A2 and the radio frequency signal in the band B1 is possible. In this case, the radio frequency signal in the band A2 passes through the low frequency side filter 10L and the duplexer 22, and the radio frequency signal in the band B1 passes through the high frequency side filter 10H and the duplexer 31. In addition, (2) simultaneous transmission of the radio frequency signal in the band A1 and the radio frequency signal in the band B1 is possible. In this case, the radio frequency signal in reception band A1-Rx of the band A1 passes through only the reception filter 21R without passing through the low frequency side filter 10L, the radio frequency signal in the transmission band A1-Tx of the band A1 passes through the low frequency side filter 10L and the transmission filter 21T, and the radio frequency signal in band B1 passes through the high frequency side filter 10H and the duplexer 31. Further (3) simultaneous transmission of the radio frequency signal in the band B2 and the radio frequency signal in the band A2 is possible. In this case, the radio frequency signal in the band B2 passes through only the transmission/reception filter 41TR without passing through the high frequency side filter 10H, and the radio frequency signal in the band A2 passes through the low frequency side filter 10L and the duplexer 22. Furthermore, (4) simultaneous transmission of the radio frequency signal in the band A1 and the radio frequency signal in the band B2 is possible. In this case, by connecting the common terminal 55a and the selection terminal 55b and connecting the common terminal 55a and the selection terminal 55c of the switch 55 (simultaneous connection), the radio frequency signal in the reception band A1-Rx of the band A1 passes through only the reception filter 21R without passing through the low frequency side filter 10L, and the radio frequency signal in the band B2 passes through only the transmission/reception filter 41TR without passing through the high frequency side filter 10H.

That is, when CA operation is executed using the radio frequency signal in the band A1 or the band B2 which at least partially overlaps the boundary band, the radio frequency signals in (the reception band A1-Rx of) the band A1 and the band B2 are set so as not to pass through the diplexer 10 in which the insertion loss deteriorates in the boundary band. Further, by not allowing the radio frequency signals in (the reception band A1-Rx of) the band A1 and the band B2 which overlap the boundary band to pass through the diplexer 10, it is possible to further relax the required specifications (for the insertion loss and the attenuation amount of the boundary band) of the diplexer 10. Therefore, even when the plurality of frequency bands overlap the boundary band, low-loss CA can be achieved by a simpler circuit configuration without complicating the diplexer 10.

Note that the radio frequency front end circuit 1D according to the present modification may not include the duplexer 22. In this case, the radio frequency front end circuit 1D can execute (1) CA using the band A1 and the band B1 and (2) CA using the band A1 and the band B2. In this case, the switch 51 is not required. In addition, the duplexer 31 may not be provided. In this case, the radio frequency front end circuit 1D can execute (1) CA using the band A1 and the band B2 and (2) CA using the band A2 and the band B2.

### Embodiment 3

In the present embodiment, an example in which bands (frequency bands) of long term evolution (LTE) are applied to the radio frequency front end circuits according to Embodiments 1 and 2 will be described.

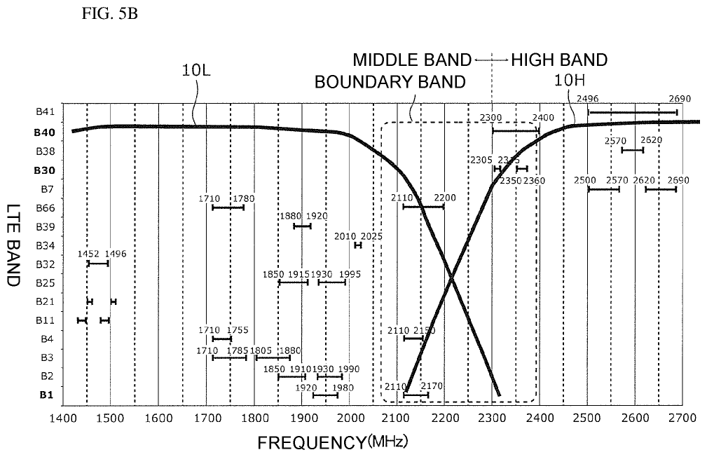

FIG. 5A is a circuit configuration diagram of a radio frequency front end circuit 1E according to Embodiment 3. FIG. 5B is a diagram illustrating a frequency relationship between bandpass characteristics of the diplexer 10 included in the radio frequency front end circuit 1E according to Embodiment 3 and the bands of LTE.

As illustrated in FIG. 5A, the radio frequency front end circuit 1E includes the diplexer 10, a plurality of filters each having a band of LTE as a pass band, switches 51A, 54A, 55A, and 56, a coupler 90, a coupler output terminal 110, and the common input/output terminal 100.

The common input/output terminal 100 is connected to the antenna element 2.

The diplexer 10 includes the common terminal 10a (first common terminal), the input/output terminal 10b (first input/output terminal), and the input/output terminal 10c (second input/output terminal), and is a multiplexer that demultiplexes and multiplexes radio frequency signals in a middle band group (first frequency band group) and radio frequency signals in a high band group (second frequency band group) located on a high frequency side of the middle band group.

The diplexer 10 includes the low frequency side filter 10L and the high frequency side filter 10H. The low frequency side filter 10L is connected between the common terminal 10a and the input/output terminal 10b, and is a low pass filter that has a plurality of bands belonging to the middle band group as a pass band and a plurality of bands belonging to the high band group as an attenuation band, as illustrated in FIG. 5B. Also, the high frequency side filter 10H is connected between the common terminal 10a and the input/output terminal 10c, and is a high pass filter that has the plurality of bands belonging to the high band group as a pass band, and the plurality of bands belonging to the middle band group as an attenuation band, as illustrated in FIG. 5B. In addition, the common terminal 10a is connected to the common input/output terminal 100.

A plurality of filters included in the radio frequency front end circuit 1E are filters each having the band of LTE illustrated in FIG. 5B as the pass band. Specifically, the radio frequency front end circuit 1E includes (i) a transmission filter B66Tx having Band 66 transmission band (1710 to 1780 MHz) as a pass band and a reception filter B66Rx having Band 66 reception band (2110 to 2200 MHz) as a pass band, (ii) a transmission filter B25Tx having Band 25 transmission band (1850 to 1915 MHz) as a pass band and a reception filter B25Rx having Band 25 reception band (1930 to 1995 MHz) as a pass band, (iii) a transmission/reception filter B34 having a transmission/reception band (2010 to 2025 MHz) of Band 34 as a pass band and a transmission/reception filter B39 having a transmission/reception band (1880 to 1920 MHz) of Band 39 as a pass band, (iv) a transmission filter B3Tx having a transmission band (1710 to 1785 MHz) of Band 3 as a pass band and a reception filter B3Rx having a reception band (1805 to 1880 MHz) of Band 3 as a pass band, (v) a transmission filter B1Tx having a transmission band (1920 to 1980 MHz) of Band 1 as a pass band and a reception filter B1Rx having a reception band (2110 to 2170 MHz) of Band 1 as a pass band, (vi) a transmission filter B30Tx having a transmission band (2305-2315 MHz) of Band 30 as a pass band and a reception filter B30Rx having a reception band (2350-2360 MHz) of Band 30 as a pass band, (vii) a transmission/reception filter B41 having a transmission/reception band (2496 to 2690 MHz) of Band 41 as a pass band, (viii) a transmission filter B7Tx having a transmission band (2500 to 2570 MHz) of Band 7 as a pass band and a reception filter B7Rx having a reception band (2620 to 2690 MHz) of Band 7 as a pass band, and (ix) a transmission/reception filter B40 having a transmission/reception band (2300 to 2400 MHz) of Band 40 as a pass band.

As illustrated in FIG. 5B, the middle band group has a frequency range of 2300 MHz or less, and includes Bands 1, 3, 25, 34, 39, and 66 of LTE. On the other hand, the high band group has a frequency range of 2300 MHz or more, and includes Bands 7, 30, 40, and 41 of LTE. Here as illustrated in FIG. 5B, Band 1 (reception band), Band 66 (reception band), Band 30, and Band 40 at least partially overlap the boundary band.

The switch 51A includes a common terminal 51a and selection terminals 51b to 51g, switches connection between the low frequency side filter 10L and the reception filter B66Rx, the duplexer B25 (transmission filter B25Tx and reception filter B25Rx), the transmission/reception filters B34 and B39, and the quadplexer (transmission filters B3Tx and B1Tx and reception filters B3Rx and B1Rx) belonging to the middle band group and a filter 2GHB.

The switch 54A includes a common terminal 54a and selection terminals 54b and 54c, and switches connection between the high frequency side filter 10H and the transmission/reception filter B41 and the duplexer B7 (transmission filter B7Tx and reception filter B7Rx) belonging to the high band group.

The switch 55A includes a common terminal 55a and selection terminals 55b, 55c, 55d, and 55e, switches connection and non-connection between the reception filter B66Rx and the common input/output terminal 100, switches connection and non-connection between the duplexer B30 (transmission filter B30Tx and reception filter B30Rx) and the common input/output terminal 100, switches connection and non-connection between the transmission/reception filter B40 and the common input/output terminal 100, and switches connection and non-connection between the reception filter B1Rx and the common input/output terminal 100. The common terminal 55a of the switch 55A is connected to the common input/output terminal 100, the selection terminal 55b is connected to one end of the reception filter B66Rx, the selection terminal 55c is connected to a common terminal of the duplexer B30, the selection terminal 55d is connected to one end of the transmission/reception filter B40, and the selection terminal 55e is connected to one end of the reception filter B1Rx.

According to the above-described configuration, the radio frequency front end circuit 1E can simultaneously transmit (execute CA using) the radio frequency signals in one or more frequency bands among the plurality of frequency bands (Bands 1, 3, 25, 34, 39, and 66) belonging to the middle band group and the radio frequency signals in one or more frequency bands among the plurality of frequency bands (Bands 7, 30, 40, and 41) belonging to the high band group.

A frequency interval is only 100 MHz between Band 66 (reception band: 2110 to 2200 MHz) located at a high frequency side end among the bands belonging to the middle band group and Band 40 (pass band: 2300 to 2400 MHz) located at a low frequency side end among the bands belonging to the high band group. For this reason, the insertion loss of the low frequency side filter 10L constituting the diplexer 10 in Band 66 (reception band) deteriorates sharply toward the high frequency side, and the insertion loss of the high frequency side filter 10H in Band 40 deteriorates sharply toward the low frequency side.

On the other hand, in the radio frequency front end circuit 1E according to the present embodiment, (1) when executing CA using the radio frequency signal in Band 66 and the radio frequency signal in the band belonging to the high band group, the radio frequency reception signal in Band 66 passes through only the reception filter B66Rx (third filter) without passing through the low frequency side filter 10L. In addition, (2) when executing CA using the radio frequency signal in Band 30 and the radio frequency signal in the band belonging to the middle band group, the radio frequency signal in Band 30 passes through only the duplexer B30 (fourth filter) without passing through the high frequency side filter 10H. Further, (3) when executing CA using the radio frequency signal in Band 40 and the radio frequency signal in the band belonging to the middle band group, the radio frequency signal in Band 40 passes through only the transmission/reception filter B40 (fourth filter) without passing through the high frequency side filter 10H. Furthermore, (4) when executing CA using the radio frequency signal in Band 1 and the radio frequency signal in the band belonging to the high band group, the radio frequency reception signal in Band 1 passes through only the reception filter B1Rx (third filter) without passing through the low frequency side filter 10L.

That is, when CA operation is executed using the radio frequency signals in Band 1, Band 66, Band 30, and Band 40 which at least partially overlap the boundary band, the radio frequency signals in (reception band of) Band 1, (reception band of) Band 66, Band 30, and Band 40 are set so as not to pass through the diplexer 10 in which the insertion loss deteriorates in the boundary band. Further, by not allowing the radio frequency signals in (the reception band of) Band 1, (the reception band of) Band 66, Band 30, and Band 40 which overlap the boundary band to pass through the diplexer 10, it is possible to further relax the required specifications in the boundary band of the diplexer 10. Therefore, even when the plurality of bands overlap the boundary band, low-loss CA can be achieved by a simpler circuit configuration without complicating the diplexer 10.

Note that the types and the numbers of the duplexers and the filters included in the radio frequency front end circuit 1E according to the present embodiment are not limited to the above-described configuration, and are arbitrarily set according to the combination of bands for executing CA.

Note that the coupler 90 and the switch 56 constitute a circuit for monitoring power intensity of the radio frequency signal transmitted between the common input/output terminal 100 and the diplexer 10, and are not essential constituent elements of the radio frequency front end circuit according to the present disclosure.

The radio frequency front end circuit 1E according to the present embodiment has a circuit configuration for executing CA operation using the radio frequency signal in the middle band group and the radio frequency signal in the high band group, but, for example, can also be applied to a circuit for executing CA operation using a radio frequency signal in a low band group (frequency range of one GHz or less) and a radio frequency signal in the middle band group (frequency range of one GHz or more).

### Other Embodiments

Although the radio frequency front end circuit and the communication device according to the present disclosure have been described above with reference to the embodiments and the modifications, the present disclosure is not limited to the above-described embodiments and modifications. Other embodiments realized by combining arbitrary constituent elements in the above-described embodiments and modifications, various modifications that a person skilled in the art can consider without departing from the spirit of the present disclosure with respect to the above-described embodiments, and various apparatuses incorporating the radio frequency front end circuits and the communication device according to the present disclosure are also included in the present disclosure.

In addition, as the diplexer 10 according to Embodiment 3, the diplexer for demultiplexing/multiplexing the middle band group and the high band group has been exemplified. However, for example, among the low band group, the middle band group, the middle high band group, and the high band group as the frequency band groups to be demultiplexed/multiplexed, a multiplexer may demultiplex/multiplex two or more band groups including two band groups with adjacent frequencies to each other.

Further, in the above-described embodiments and modifications, the radio frequency front end circuit for the transmission/reception system is exemplified, but the radio frequency front end circuit may be for only the transmission system or only the reception system.

Furthermore, for example, in the radio frequency front end circuit and the communication device according to the embodiments and the modifications, matching elements such as an inductor, a capacitor, and the like and a switch circuit may be connected between the respective constituent elements. Note that the inductor may include a wiring inductor formed of a wiring connecting between the respective constituent elements.

The present disclosure can be widely used for a communication apparatus such as a mobile phone as a radio frequency front end circuit and a communication device applicable to a multi-band system that executes CA mode.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A radio frequency front end circuit configured to simultaneously transmit a first radio frequency signal in a first frequency band group, and second a radio frequency signal in a second frequency band group, the second frequency band group comprising higher frequencies than the first frequency band group, the radio frequency front end circuit comprising:
a common input/output terminal connected to an antenna;
a multiplexer comprising a first common terminal, a first input/output terminal, and a second input/output terminal, and configured to demultiplex and/or multiplex the first high frequency signal and the second high frequency signal;
a first filter having a pass band that comprises the first frequency band;
a second filter having a pass band that comprises the second frequency band; and
a third filter having a pass band that overlaps a boundary band of the first frequency band group and the second frequency band group, the boundary band comprising frequencies on a high frequency side of the first frequency band group and a low frequency side of the second frequency band group, wherein:
the multiplexer comprises:
a low frequency side filter connected between the first common terminal and the first input/output terminal, and having a pass band comprising a plurality of frequency bands of the first frequency group, and an attenuation band comprising a plurality of frequency bands of the second frequency band group, and
a high frequency side filter connected between the first common terminal and the second input/output terminal, and having a pass band comprising the plurality of frequency bands of the second frequency band group, and an attenuation band comprising the plurality of frequency bands of the first frequency band group,
the first common terminal is connected to the common input/output terminal,
a first end of the first filter is connected to the first input/output terminal,
a first end of the second filter is connected to the second input/output terminal, and
a first end of the third filter is connected to the common input/output terminal without passing through the multiplexer.

2. The radio frequency front end circuit according to claim 1, further comprising:
a switch between the first end of the third filter and the common input/output terminal, the switch being configured to selectively connect the third filter to the common input/output terminal.

3. The radio frequency front end circuit according to claim 2, wherein:
the third filter has a pass band comprising a third frequency band that is of the first frequency band group and that overlaps the boundary band,
the radio frequency front end circuit further comprises a fourth filter having a pass band comprising a fourth frequency band that is of the second frequency band group and that overlaps the boundary band,
the switch comprises a second common terminal, a first selection terminal, and a second selection terminal, and is configured to selectively connect the second common terminal between the first selection terminal and the second selection terminal,
the second common terminal is connected to the common input/output terminal without passing through the multiplexer,
the first selection terminal is connected to the first end of the third filter, and
the second selection terminal is connected to a first end of the fourth filter.

4. The radio frequency front end circuit according to claim 1, further comprising:
a phase shifter between the first end of the third filter and the common input/output terminal.

5. The radio frequency front end circuit according to claim 1, wherein:
the third frequency band comprises a third transmission band and a third reception band,
one of the third transmission band and the third reception band overlaps the boundary band, and the other of the third transmission band and the third reception band does not overlap the boundary band,
the pass band of the third filter comprises the third transmission band or the third reception band,
the radio frequency front end circuit further comprises a fifth filter having a pass band comprising the other of the third transmission band and the third reception band, and
a first end of the fifth filter is connected to the first input/output terminal or the second input/output terminal.

6. The radio frequency front end circuit according to claim 1, wherein the radio frequency front end circuit is configured to execute carrier aggregation for simultaneously transmitting at least two of a radio frequency signal passing through the first filter, a radio frequency signal passing through the second filter, and a radio frequency signal passing through the third filter.

7. The radio frequency front end circuit according to claim 1, wherein:
the first frequency band group is a middle band group having a frequency range of 2300 MHz or less,
the second frequency band group is a high band group having a frequency range of 2300 MHz or more,
the low frequency side filter is a low pass filter, the high frequency side filter is a high pass filter, and
the multiplexer is a diplexer comprising the low pass filter and the high pass filter.

8. The radio frequency front end circuit according to claim 7, wherein the third filter is a Band 30, Band 40, or Band 1 of long term evolution (LTE) filter.

9. The radio frequency front end circuit according to claim 1, further comprising:
an amplifier circuit connected to a second end of the first filter, a second end of the second filter, and a second end of the third filter.

10. A communication device comprising:
a radio frequency integrated circuit configured to process a radio frequency signal received by an antenna; and
the radio frequency front end circuit according to claim 9 configured to transmit the radio frequency signal between the antenna and the radio frequency integrated circuit.
